(19) United States
(12) Patent Application Publication
(10) Pub. No.: US 2025/0126890 A1
(43) Pub. Date: Apr. 17, 2025

(54) DISPLAY APPARATUS, ARRAY SUBSTRATE, AND THIN-FILM TRANSISTOR

(71) Applicant: BOE Technology Group Co., Ltd., Beijing (CN)

(72) Inventor: Pengfei GU, Beijing (CN)

(21) Appl. No.: 18/688,058

(22) PCT Filed: Jan. 29, 2023
(86) PCT No.: PCT/CN2023/073646

§ 371 Date: Feb. 29, 2024

(51) Int. Cl. H10D 86/40

(52) U.S. Cl. CPC H10D 86/441; H10D 86/451

(57) ABSTRACT

The present disclosure provides a display apparatus, an array substrate, and a thin-film transistor. The thin-film transistor includes: an active layer, including a channel region and two source/drain regions, the two source/drain regions are at two opposite sides of the channel region, the source/drain regions are spaced apart from the channel region, the regions of the active layer between the source/drain regions and the channel region are conductorization regions; the first source/drain electrode portion and the second source/drain electrode portion are correspondingly connected with the two source/drain regions, the second source/drain electrode portion is on a side of the interlayer insulation layer away from the substrate, and an orthographic projection of the second source/drain electrode portion on the active layer overlaps with the conductorization region. The present disclosure is beneficial for the preparation of small-sized thin-film transistors

### TECHNICAL FIELD

The present disclosure relates to the field of display technology, and in particular, to a display apparatus, an array substrate, and a thin-film transistor.

### BACKGROUND

With the development of technologies, display apparatuses have garnered increasing attention. The display apparatuses generally include thin-film transistors. Existing thin film transistors still need to be improved.

### SUMMARY

The purpose of the present disclosure is to provide a display apparatus, an array substrate, and a thin-film transistor, which is beneficial for the preparation of small-sized thin-film transistors.

According to an aspect of the present disclosure, a thin-film transistor is provided to be applied to an array substrate, wherein, the array substrate includes a substrate, the thin-film transistor includes:

an active layer, arranged on a side of the substrate, and including: a channel region and two source/drain regions, where the two source/drain regions are at two opposite sides of the channel region, the source/drain regions are spaced apart from the channel region, and regions of the active layer between the source/drain regions and the channel region are conductorization regions;

a gate insulation layer on a side of the active layer away from the substrate;

a gate electrode on a side of the gate insulation layer away from the substrate, corresponding to the channel region;

an interlayer insulation layer, on a side of the gate electrode away from the substrate;

source/drain electrodes, including a first source/drain electrode portion and a second source/drain electrode portion, the first source/drain electrode portion and the second source/drain electrode portion are correspondingly connected with the two source/drain regions, the second source/drain electrode portion is on a side of the interlayer insulation layer away from the substrate, and an orthographic projection of the second source/drain electrode portion on the active layer overlaps with the conductorization regions.

Further, two of the conductorization regions are within an orthographic projection region of the second source/drain electrode portion on the active layer.

Further, the first source/drain electrode portion is arranged on a side of the gate insulation layer away from the substrate, the interlayer insulation layer covers the first source/drain electrode portion.

Further, the first source/drain electrode portion is on a same layer as the gate electrode.

Further, the second source/drain electrode portion is of a strip-shaped structure, and an extension direction of the second source/drain electrode portion is the same as a distribution direction of the two source/drain regions; a partial region of the first source/drain electrode portion is on a side in a width direction of the second source/drain electrode portion.

Further, the first source/drain electrode portion includes a first electrode strip and a second electrode strip, an extension direction of the first electrode strip intersects with an extension direction of the second source/drain electrode portion, an end of the first electrode strip is connected with one of the two source/drain regions through a first via hole, an orthographic projection of the second electrode strip on the substrate is spaced apart from the second source/drain electrode portion, and the second electrode strip is connected with an other end of the first electrode strip.

Further, the first source/drain electrode portion is on a surface of the active layer away from the substrate, and the interlayer insulation layer covers the first source/drain electrode portion.

Further, one of the conductorization regions is within an orthographic projection region of the second source/drain electrode portion on the active layer;

an other one of the conductorization regions is partially within the orthographic projection region of the second source/drain electrode portion on the active layer; or, the other one of the conductorization regions is spaced apart from the orthographic projection of the second source/drain electrode portion on the active layer.

Further, the first source/drain electrode portion is on a surface of the interlayer insulation layer away from the substrate.

Further, thin-film transistor includes:

a light shielding layer, between the substrate and the active layer, wherein an orthographic projection of the active layer on the substrate is within an orthographic projection region of the light shielding layer on the substrate.

Further, the light shielding layer is made of conductive material;

the light shielding layer is connected with the first source/drain electrode portion; or, the light shielding layer is connected with the gate electrode.

According to an aspect of the present disclosure, an array substrate is provided, including a plurality of the thin-film transistors distributed in an array.

Further, the plurality of thin-film transistors distributed in an array form a plurality of transistor rows and a plurality of transistor columns, second source/drain electrode portions of a plurality of thin-film transistors in one of the transistor columns are connected in sequence, and gate electrodes of a plurality of thin-film transistors in one of the transistor rows are connected in sequence.

According to an aspect of the present disclosure, a display apparatus is provided, including the array substrate.

In the display apparatus, the array substrate, and the thin-film transistor of the present disclosure, the second source/drain electrode portion is on a side of the interlayer insulation layer away from the substrate, and the orthographic projection of the second source/drain electrode portion on the active layer overlaps with the conductorization region. Such an arrangement, when a positive potential is loaded on the second source/drain electrode portion, is to generate carrier electrons in the conductorization region of the active layer through the interlayer insulation layer, enhancing the conductorization, therefore, avoiding the use of conductorization processes in the related art, avoiding element diffusion in the related art, which is beneficial for the preparation of small-sized thin-film transistors.

### BRIEF DESCRIPTION OF DRAWINGS

FIG. 1 is a schematic diagram of a thin-film transistor in the related art.

FIG. 2A is a schematic diagram of a thin-film transistor after forming a first via hole according to an embodiment of the present disclosure.

FIG. 2B is an A-A′ cross-sectional view of the structure illustrated in FIG. 2A.

FIG. 3A is a schematic diagram of a thin-film transistor after forming a gate electrode according to an embodiment of the present disclosure.

FIG. 3B is an A-A′ cross-sectional view of the structure illustrated in FIG. 3A.

FIG. 4A is a schematic diagram of a thin-film transistor after forming a second via hole according to an embodiment of the present disclosure.

FIG. 4B is an A-A′ cross-sectional view of the structure illustrated in FIG. 4A.

FIG. 5A is a schematic diagram of a thin-film transistor after forming a second source/drain electrode portion according to an embodiment of the present disclosure.

FIG. 5B is an A-A′ cross-sectional view of the structure illustrated in FIG. 5A.

FIGS. 6 and 7 are schematic diagrams of a thin-film transistor according to an embodiment of the present disclosure.

FIG. 8 is a schematic diagram of another thin-film transistor after forming an active layer according to an embodiment of the present disclosure.

FIG. 9 is a schematic diagram of another thin-film transistor after forming a gate insulation layer according to an embodiment of the present disclosure.

FIG. 10 is a schematic diagram of another thin-film transistor after forming the gate electrode according to an embodiment of the present disclosure.

FIG. 11 is a schematic diagram of another thin-film transistor after forming an interlayer insulation layer according to an embodiment of the present disclosure.

FIG. 12 is a schematic diagram of a thin-film transistor after forming the second source/drain electrode portion according to an embodiment of the present disclosure.

FIG. 13 is a schematic diagram of a plurality of thin-film transistors according to an embodiment of the present disclosure.

Description of reference numerals: 1, substrate; 2, active layer; 201, channel region; 202, source/drain region; 203, conductorization region; 3, gate insulation layer; 4, interlayer insulation layer; 5, first source/drain electrode portion; 501, first electrode strip; 502, second electrode strip; 6, second source/drain electrode portion; 7, gate electrode; 8, first via hole; 9, second via hole; 10, light shielding layer; 11, buffer layer; 12, third via hole.

### DETAILED DESCRIPTION

Exemplary embodiments will be described in detail here, examples of which are illustrated in the accompanying drawings. When the following description relates to the accompanying drawings, unless specified otherwise, the same numerals in different drawings represent the same or similar elements. The implementations described in the following examples do not represent all implementations consistent with the present disclosure. Rather, they are merely device examples consistent with some aspects of the present disclosure as detailed in the appended claims.

The terms used in the present disclosure are for the purpose of describing a particular example only, and is not intended to limit the present disclosure. Unless otherwise defined, the technical or scientific terms used in the present disclosure shall have the usual meanings understood by those of ordinary skill in the field to which the present disclosure belongs. It is to be understood that, “first”, “second” and similar terms used in the specification and the claims of this patent application do not indicate any sequence or importance, but are only used to distinguish different components. Similarly, “one”, “a”, and similar terms also do not indicate a quantity limitation, but indicates that there is at least one. The term “a plurality” indicates two or more, unless specifically defined otherwise. Unless otherwise stated, the terms such as “front”, “rear”, “lower”, and/or “upper” are for ease of description only and are not limited to a position or a spatial orientation. The terms such as “comprise”, “include”, or any variant thereof mean that an element or an article preceded by “comprise” or “include” encompasses elements or articles and their equivalents listed after “comprise” or “include”, do not exclude the existence of other elements or articles. “Connected to” or “connected with” and similar terms are not limited to physical or mechanical connections, and can include electrical connections, whether direct or indirect. Terms like “a”, “the” and “said” in their singular forms in the present disclosure and the appended claims are also intended to include plurality, unless clearly indicated otherwise in the context. It should also be understood that the term “and/or” used herein includes any and all possible combinations of one or more of the associated listed items.

In the related art, reducing the thin-film transistors (TFT) layout area is an important solution to increase the pixel density (ppi) of display apparatuses. To reduce the TFT layout area, it is necessary to develop small-sized TFT, e.g., the length of the channel region 201 of a TFT is less than or equal to 3 μm, or the width of the channel region 201 of a TFT is less than or equal to 3 μm.

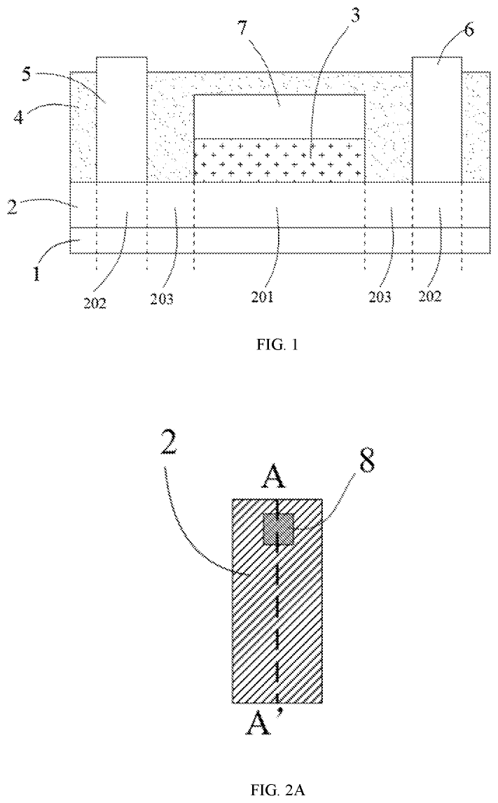

FIG. 1 illustrates a structure of an oxide TFT, which is a top-gate type structure. The active layer 2 may include a channel region 201 and two source/drain regions 202, the two source/drain regions 202 are arranged at two opposite sides of the channel region 201, the source/drain regions are arranged to be spaced apart from the channel region 201, and regions of the active layer 2 located between the source/drain regions 202 and the channel region 201 are conductorization regions 203. The conductorization region 203 is not covered by the gate electrode 7, when the device is running, a high-resistance state occurs, the on-state current of the source electrode of the TFT or the on-state current of the drain electrode (one of the first source/drain electrode portion 5 and the second source/drain electrode portion 6 of FIG. 1 is a source electrode, and the other is a drain electrode) of the TFT is reduced by several orders of magnitude, and thus the conductorization region 203 needs to be conductive. Common conductorization processes include: He plasma, Ar plasma, low-oxygen interlayer insulation layer, and NH₃ plasma, the principle of which may be attributed to the generation of donor defects such as oxygen vacancies or hydrogen gaps in the conductorization region 203, causing a large number of charge carriers (electrons) to be generated in this region. However, regardless of which conductorization process is used, it may result in a certain element concentration difference (oxygen or hydrogen concentration difference) between the conductorization region 203 and the channel region 201. Under annealing, element diffusion occurs between the conductorization region 203 and the channel region 201, and the higher the degree of conductorization, the more severe the diffusion. For traditional top-gate oxide TFTs, when the length of the channel region 201 of the TFT is close to 3 μm, due to the element diffusion between the conductorization region 203 and the channel region 201, the characteristics of the TFT are prone to anomalies, such as negative bias in threshold voltage, which makes it difficult to prepare a small-sized TFT.

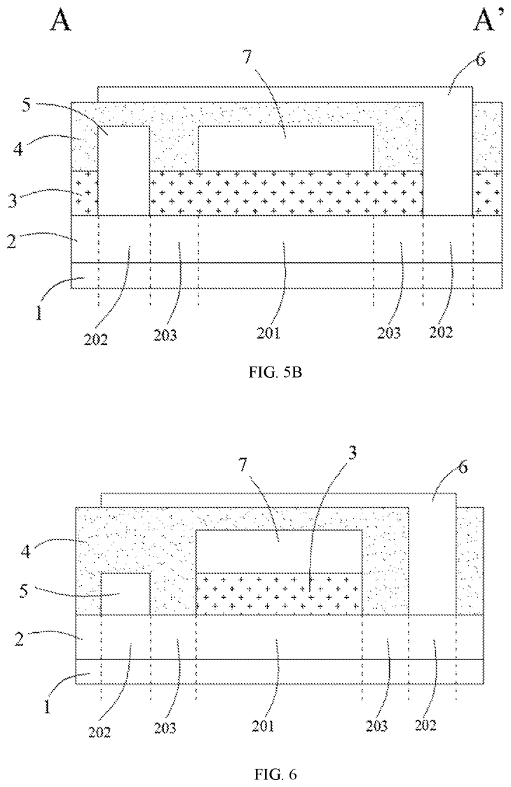

A TFT is provided by an embodiment of the present disclosure. The TFT may be applied to an array substrate. The array substrate may include a substrate 1. As illustrated in FIGS. 5A and 5B, the TFT may include an active layer 2, a gate insulation layer 3, a gate electrode 7, an interlayer insulation layer 4, and source/drain electrodes.

The active layer 2 may be arranged on a side of the substrate 1. The active layer 2 may include a channel region 201 and two source/drain regions 202. The two source/drain regions 202 are correspondingly arranged at two opposite sides of the channel region 201. The source/drain regions 202 are arranged to be spaced apart from the channel region 201. The regions of the active layer 2 located between the source/drain regions 202 and the channel region 201 are conductorization regions 203. The gate insulation layer 3 may be arranged on a side of the active layer 2 away from the substrate 1. The gate electrode 7 may be arranged on a side of the gate insulation layer 3 away from the substrate 1, and corresponding to the channel region 201. The interlayer insulation layer 4 may be arranged on a side of the gate electrode 7 away from the substrate 1, and the source/drain electrode may include the first source/drain electrode portion 5 and the second source/drain electrode portion 6. The first source/drain electrode portion 5 and the second source/drain electrode portion 6 are correspondingly connected with the two source/drain regions 202. The second source/drain electrode portion 6 is arranged on a side of the interlayer insulation layer 4 away from the substrate 1, and an orthographic projection of the second source/drain electrode portion 6 on the active layer 2 overlaps with the conductorization region 203.

In the TFT according to embodiments of the present disclosure, the second source/drain electrode portion 6 is arranged on a side of the interlayer insulation layer 4 away from the substrate 1, and the orthographic projection of the second source/drain electrode portion 6 on the active layer 2 overlaps with the conductorization region 203. Such an arrangement, when a positive potential is loaded on the second source/drain electrode portion 6, is to generate carrier electrons in the conductorization region 203 of the active layer 2 through the interlayer insulation layer 4, enhancing the conductorization, and thus the conductorization process in the related art may be avoided or the requirements of the conductorization process may be reduced, reducing the element diffusion in the related art, which is beneficial for the preparation of small-sized TFTs.

The following provides a detailed description of aspects of the TFT according to the embodiments of the present disclosure.

As illustrated in FIGS. 5A and 5B, the active layer 2 may be arranged on a side of the substrate 1. The material of the active layer 2 may be an oxide, such as Indium gallium zinc oxide (IGZO), etc. The mass percentage of oxygen in the active layer 2 is 5%-60%. The orthographic projection of the active layer 2 on the substrate 1 may be rectangular or strip-shaped, but the present disclosure is not limited thereto. For example, if the orthographic projection of the active layer 2 on the substrate 1 is rectangular, then the long side direction of the orthographic projection of the active layer 2 is the first direction. For example, if the orthographic projection of the active layer 2 on the substrate 1 is strip-shaped, then the extension direction of the orthographic projection of the active layer 2 is the first direction. The active layer 2 may include a channel region 201 and the source/drain regions 202. The quantity of the source/drain regions 202 may be two, and the two source/drain regions 202 are arranged at two opposite sides of the channel region 201. Specifically, in the above-mentioned first direction, the two source/drain regions 202 are arranged at two opposite sides of the channel region 201 in a one-to-one correspondence manner. The source/drain regions 202 are arranged to be spaced apart from the channel region 201. The channel region 201 is arranged spaced apart from both of the source/drain regions 202. The regions of the active layer 2 located between the source/drain regions 202 and the channel region 201 are conductorization regions 203, and since the quantity of the source/drain regions 202 is two, the quantity of the conductorization regions 203 is also two. In addition, a buffer layer 11 (Buffer) may be provided between the active layer 2 and the substrate 1 (see FIG. 12).

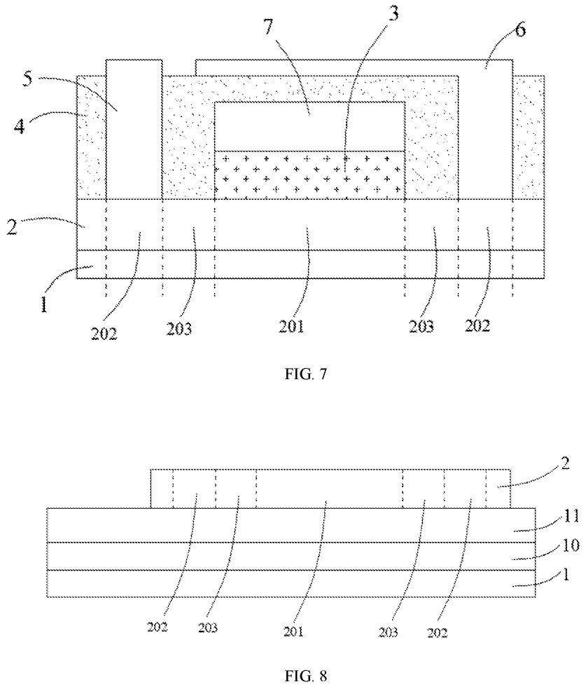

The gate insulation layer 3 may be arranged on a side of the active layer 2 away from the substrate 1. In an embodiment of the present disclosure, as illustrated in FIG. 5A, the orthographic projection of the active layer 2 on the substrate 1 is located within the orthographic projection region of the gate insulation layer 3 on the substrate 1. In another embodiment of the present disclosure, as illustrated in FIGS. 6 and 7, the above-mentioned channel region 201 is located within the orthographic projection region of the gate insulation layer 3 on the active layer 2, and the area of the channel region 201 is the same as the area of the orthogonal projection of the gate insulating layer 3 on the active layer 2, that is, the orthographic projection of the gate insulation layer 3 on the active layer 2 does not overlap with the conductorization regions 203, and the orthographic projection of the gate insulation layer 3 on the active layer 2 does not overlap with the source/drain regions 202. The gate insulation layer 3 may be a single-layer structure, e.g., a SiOx film layer or a SiNx film layer, of course, the material of the single-layer structure may be a mixture, which may include both SiOx and SiNx. In other embodiments of the present disclosure, the gate insulation layer 3 may be a stacked structure. The stacked structure of the gate insulation layer 3 may include SiOx film layers and SiNx film layers that are arranged in a stacked manner.

As illustrated in FIGS. 5A and 5B, the gate electrode 7 may be arranged on a side of the gate insulation layer 3 away from the substrate 1, and corresponding to the channel region 201. The orthographic projection of the gate electrode 7 on the active layer 2 may completely overlap with the channel region 201, that is, the area of the orthographic projection of the gate electrode 7 on the active layer 2 is the same as the area of the channel region 201, and the region of the active layer 2 corresponding to gate electrode 7 is the channel region 201. The gate electrode 7 may be a stacked structure, such as Mo/Al/Mo, that is, the stacked structure includes a metal Mo layer, a metal Al layer, and a metal Mo layer that are arranged in a stacked manner. Of course, the stacked structure of the gate electrode 7 may also be Ti/Al/Ti, but the present disclosure is not limited thereto, and the stacked structure of the gate electrode 7 may also be Mtd/Cu/Mtd.

As illustrated in FIG. 5B, the interlayer insulation layer 4 may be arranged on a side of the gate electrode 7 away from the substrate 1. The orthographic projection of the active layer 2 on the substrate 1 may be located within the orthographic projection region of the interlayer insulation layer 4 on the substrate 1. The orthographic projection of the gate insulation layer 3 on the substrate 1 may be located within the orthographic projection region of the interlayer insulation layer 4 on the substrate 1. The orthographic projection of the gate electrode 7 on the substrate 1 may be located within the orthographic projection region of the interlayer insulation layer 4 on the substrate 1. The interlayer insulation layer 4 may be a single-layer structure, e.g., a SiOx film layer or a SiNx film layer, of course, the material of the single-layer structure may be a mixture, which may include both SiOx and SiNx. In other embodiments of the present disclosure, the interlayer insulation layer 4 may be a stacked structure. The stacked structure of the interlayer insulation layer 4 may include SiOx film layers and SiNx film layers that are arranged in a stacked manner.

As illustrated in FIGS. 5A and 5B, the source/drain electrode may include the first source/drain electrode portion 5 and the second source/drain electrode portion 6. The first source/drain electrode portion 5 and the second source/drain electrode portion 6 are correspondingly connected with the two source/drain regions 202, that is, the first source/drain electrode portion 5 is connected with one source/drain region 202 of the two source/drain regions 202, and the second source/drain electrode portion 6 is connected with the other source/drain region 202 of the two source/drain regions 202. Among the two source/drain electrode portions, one source/drain electrode portion constitutes the source electrode of the TFT, and the other source/drain electrode portion constitutes the drain electrode of the TFT. The TFT may be a symmetrical TFT, and of course, the TFT may also be an asymmetrical TFT.

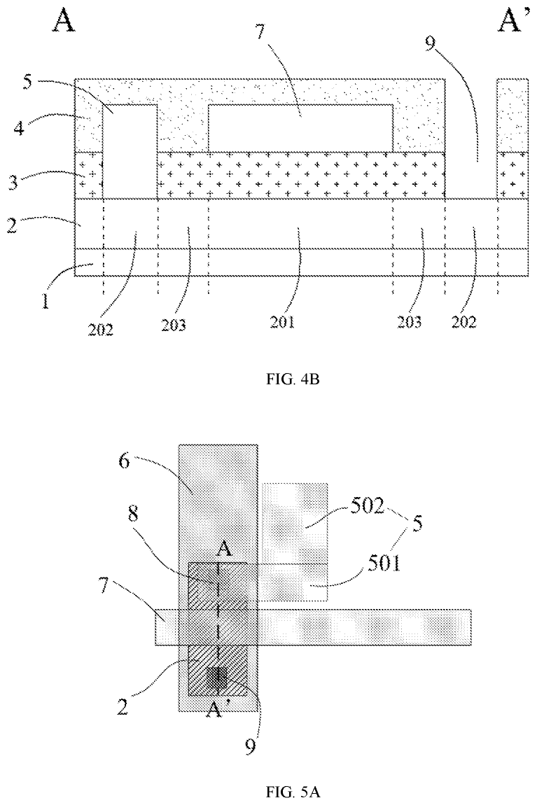

The second source/drain electrode portion 6 may be arranged on a side of the interlayer insulation layer 4 away from the substrate 1, and connected with the source/drain region 202 through the second via hole 9 [see FIGS. 4B and 5A]. The orthographic projection of the second source/drain electrode portion 6 on the active layer 2 overlaps with the conductorization region 203. Such an arrangement, when a positive potential is loaded on the second source/drain electrode portion 6, is to generate carrier electrons in the conductorization region 203 of the active layer 2 through the interlayer insulation layer 4, enhancing the conductorization. The second source/drain electrode portion 6 may be of a strip-shaped structure, and the extension direction of the second source/drain electrode portion 6 is the same as the distribution direction of the two source/drain regions 202, i.e., the extension direction of the second source/drain electrode portion 6 is the same as the above-mentioned first direction. The present disclosure regards the direction perpendicular to the first direction as the second direction, the second source/drain electrode portion 6 may be of a strip-shaped structure, that is, the size of the second source/drain electrode portion 6 in the first direction is greater than the size of the second source/drain electrode portion 6 in the second direction.

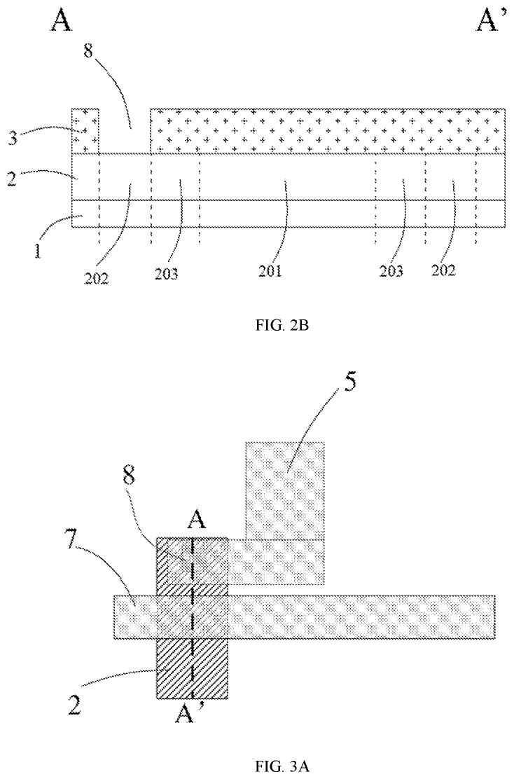

In an embodiment, as illustrated in FIGS. 5A and 5B, the two conductorization regions 203 are located within the orthographic projection region of the second source/drain electrode portion 6 on the active layer 2, that is, the orthographic projection of the second source/drain electrode portion 6 on the active layer 2 completely covers the two conductorization regions 203. For example, if the channel region 201, the conductorization regions 203, and the source/drain region 202 are all located within the orthographic projection region of the gate insulation layer 3 on the active layer 2, the first source/drain electrode portion 5 may be arranged on a side of the gate insulation layer 3 away from the substrate 1, the first source/drain electrode portion 5 is connected with the source/drain region 202 through the first via hole 8 [see FIGS. 2A and 2B], the interlayer insulation layer 4 covers the first source/drain electrode portion 5, the first source/drain electrode portion 5 may be arranged on the same layer as the gate electrode 7, and a partial region of the first source/drain electrode portion 5 is located at a side in a width direction of the second source/drain electrode portion 6. For example, if the second source/drain electrode portion 6 may be a strip-shaped structure, the width direction of the second source/drain electrode portion 6 is perpendicular to the extension direction of the second source/drain electrode portion 6. Of course, as illustrated in FIG. 6, the first source/drain electrode portion 5 may be arranged on the surface of the active layer 2 facing away from the substrate 1, and the interlayer insulation layer 4 covers the first source/drain electrode portion 5, that is, the first source/drain electrode portion 5 is arranged to be spaced apart from the gate insulation layer 3. As illustrated in FIG. 5A, the first electrode portion 5 may include the first electrode strip 501 and the second electrode strip 502. The extension direction of the first electrode strip 501 may intersect, for example, perpendicular or roughly perpendicular, with the extension direction of the second source/drain electrode portion 6. An end of the first electrode strip 501 is connected with the source/drain region 202 through a first via hole 8, the orthographic projection of the second electrode strip 502 on the substrate 1 is arranged to be spaced apart from the second source/drain electrode portion 6, and the second electrode strip is connected with the other end of the first electrode strip 501. Among the two ends of the first electrode strip 501, the end of the first electrode strip 501 connected with the second electrode strip 502 is located on a side in a width direction of the second source/drain electrode portion 6.

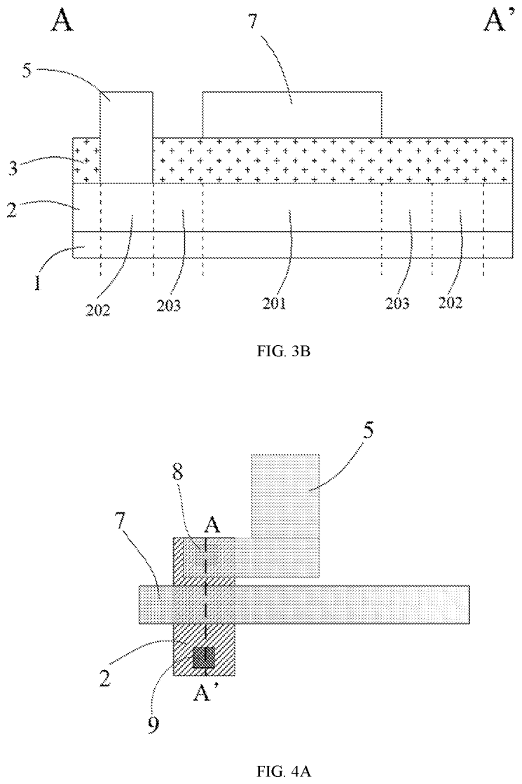

When preparing the TFT illustrated in FIGS. 5A and 5B, as illustrated in FIGS. 2A and 2B, firstly, the active layer 2 and the gate insulation layer 3 may be formed on the substrate 1, and the first via hole 8 may be formed in the gate insulation layer 3; next, as illustrated in FIGS. 3A and 3B, the gate electrode 7 and the first source/drain electrode portion 5 may be formed on the basis of the structure illustrated in FIGS. 2A and 2B; next, as illustrated in FIGS. 4A and 4B, the interlayer insulation layer 4 may be formed on the basis of the structure illustrated in FIGS. 3A and 3B, and then the second via hole 9 may be formed in the interlayer insulation layer 4; lastly, the second source/drain electrode portion 6 may be formed on the basis of the structure illustrated in FIGS. 4A and 4B.

In another embodiment, as illustrated in FIG. 7, a conductorization region 203 is located within the orthographic projection region of the second source/drain electrode portion 6 on the active layer 2, the other conductorization region 203 is partially located within the orthographic projection region of the second source/drain electrode portion 6 on the active layer 2, and the first source/drain electrode portion 5 may be arranged on the surface of the interlayer insulation layer 4 facing away from the substrate 1.

In other embodiments of the present disclosure, a conductorization region 203 is located within the orthographic projection region of the second source/drain electrode portion 6 on the active layer 2, the other conductorization region 203 is arranged to be spaced apart from the orthographic projection of the second source/drain electrode portion 6 on the active layer 2, and the first source/drain electrode portion 5 may be arranged on the surface of the interlayer insulation layer 4 facing away from the substrate 1.

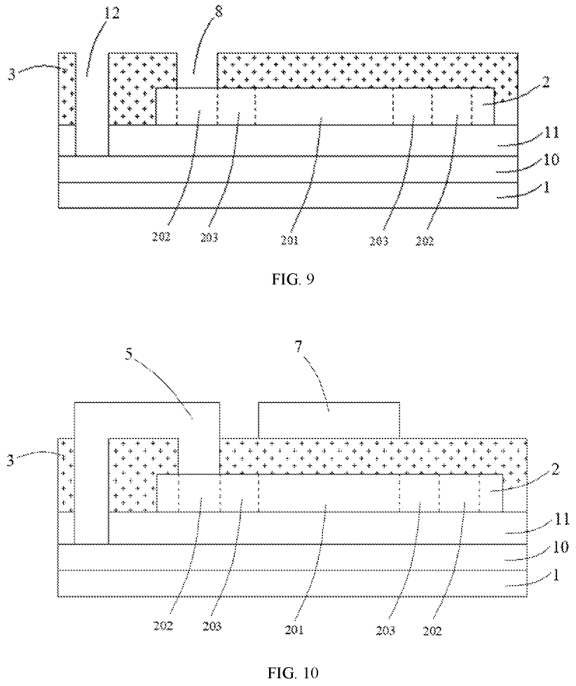

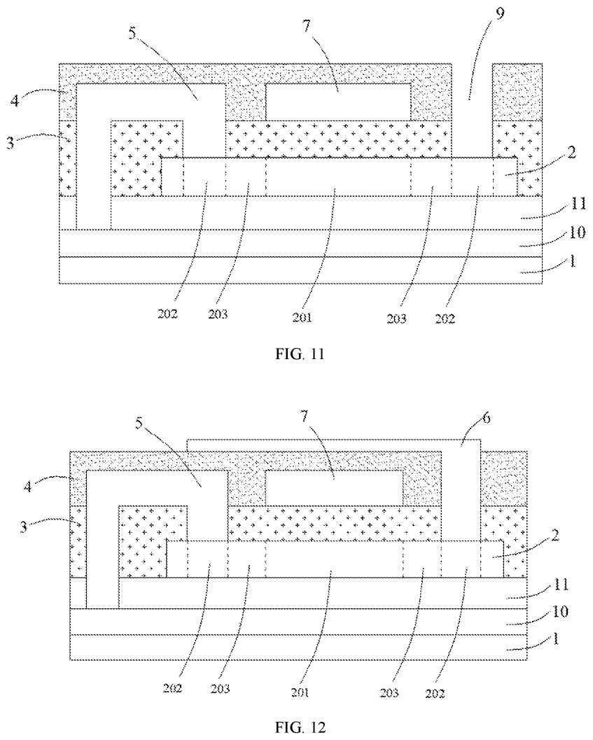

As illustrated in FIG. 12, the TFT according to an embodiment of the present disclosure may include a light shielding layer 10. The light shielding layer 10 may be arranged between the substrate 1 and the active layer 2, and the orthographic projection of the active layer 2 on the substrate 1 is located within the orthographic projection region of the light shielding layer 10 on the substrate 1. Such an arrangement may reduce the degree of negative shift for the threshold voltage of the TFT under illumination. The light shielding layer 10 may include a light absorbing material. In addition, the light shielding layer 10 may also be a conductive material, such as a metal, etc. The light shielding layer 10 may be a stacked structure, such as Mo/Al/Mo, that is, the stacked structure includes a metal Mo layer, a metal Al layer, and a metal Mo layer that are arranged in a stacked manner. Of course, the stacked structure of the light shielding layer 10 may also be Ti/Al/Ti, but the present disclosure is not limited thereto, or the stacked structure of the light shielding layer 10 may also be Mtd/Cu/Mtd. In an embodiment, the light shielding layer 10 may be electrically connected with the first source/drain electrode portion 5, where the light shielding layer 10 may be connected with the first source/drain electrode portion 5 through the third via hole 12 (see FIG. 9). When preparing the TFT including the light shielding layer 10, firstly, the light shielding layer 10, the buffer layer 11, and the active layer 2 (see FIG. 8) may be formed on the substrate 1; next, the active layer 2 is formed, and the first via hole 8 and the third via hole 12 are formed in the active layer 2 (see FIG. 9); then, the gate electrode 7 and the first source/drain electrode portion 5 are formed (see FIG. 10); then, the interlayer insulation layer 4 is formed, and the second via hole 9 is formed in the interlayer insulation layer 4 (see FIG. 11); next, the second source/drain electrode portion 6 is formed (see FIG. 12). In another embodiment, the light shielding layer 10 may be connected with the gate electrode 7.

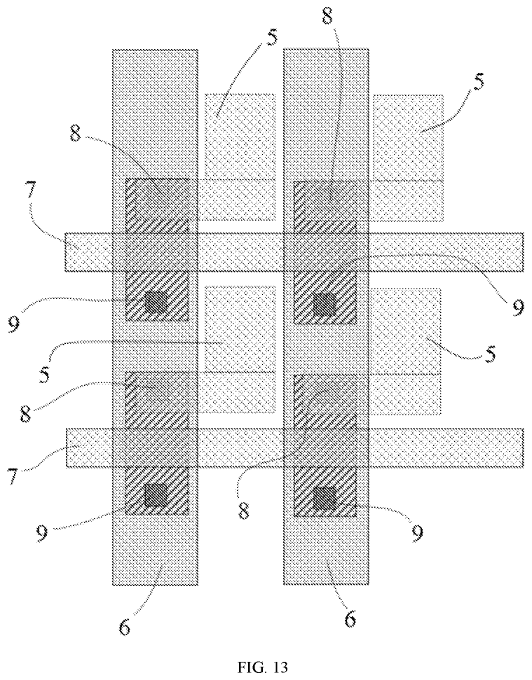

An array substrate is further provided by an embodiment of the present disclosure. The array substrate may include a plurality of TFTs described in any one of the above embodiments, and the plurality of TFTs are distributed in an array. As illustrated in FIG. 13, the plurality of TFTs distributed in an array form a plurality of transistor rows and a plurality of transistor columns, the second source/drain electrode portions 6 of the plurality of TFTs in one of the transistor columns are connected in sequence, and the gates 7 of the plurality of TFTs in one of the transistor rows are connected in sequence. The plurality of transistors in the transistor column may be distributed along the above-mentioned first direction, and the plurality of transistors in the transistor row may be distributed along the direction perpendicular to the first direction. A linear structure (vertical straight line in FIG. 13) may be formed by connecting the above-mentioned second source-drain electrode portions 6 of the plurality of TFTs in sequence, and a linear structure (horizontal straight line in FIG. 13) may be formed by connecting the above-mentioned gate electrode 7 of the plurality of TFTs in sequence. The linear structure formed by the second source/drain electrode portions 6 of the plurality of TFTs may serve as a power signal line or a data signal line for a display apparatus. Since the TFT is directly below the power signal lines or data signal lines, the image resolution (ppi) of the display apparatus may be improved.

A display apparatus is further provided by an embodiment of the present disclosure. The display apparatus may include the array substrate described in any one of the above embodiments. The display apparatus may be a liquid crystal display (LCD) apparatus. The display apparatus may further include an opposite substrate arranged substantially opposite to the array substrate, and a liquid crystal layer arranged between the array substrate and the opposite substrate.

The display apparatus, the array substrate, and the TFT provided in the present disclosure belong to the same inventive concept, the descriptions of related details and beneficial effects may be referred to each other, and will not be repeated.

The above embodiments are only the preferred embodiments of the present disclosure, and do not limit the present disclosure in any form. Although the present disclosure has been disclosed as the above with the preferred embodiments, it is not intended to limit the present disclosure. Anyone who is familiar with this art, within the scope of not departing from the technical solution of the present disclosure, can use the technical contents disclosed above to make some changes or modifications to equivalent embodiments of equivalent changes. However, within the contents of the technical solution of the present disclosure, any simple alterations, equal changes and modifications made to the above embodiments based on the technology substantially of the present disclosure should fall within the scope of the technical solution of the present disclosure.

1. A thin-film transistor, applied to an array substrate, wherein, the array substrate comprises a substrate, the thin-film transistor comprises:
an active layer on a side of the substrate and comprising a channel region and two source/drain regions, wherein the two source/drain regions are at two opposite sides of the channel region, the source/drain regions are spaced apart from the channel region, and regions of the active layer between the source/drain regions and the channel region are conductorization regions;
a gate insulation layer on a side of the active layer away from the substrate;
a gate electrode on a side of the gate insulation layer away from the substrate and corresponding to the channel region;
an interlayer insulation layer on a side of the gate electrode away from the substrate; and
source/drain electrodes comprising a first source/drain electrode portion and a second source/drain electrode portion, wherein the first source/drain electrode portion and the second source/drain electrode portion are correspondingly connected with the two source/drain regions, the second source/drain electrode portion is on a side of the interlayer insulation layer away from the substrate, and an orthographic projection of the second source/drain electrode portion on the active layer overlaps with the conductorization regions.

2. The thin-film transistor according to claim 1, wherein, two of the conductorization regions are within an orthographic projection region of the second source/drain electrode portion on the active layer.

3. The thin-film transistor according to claim 1, wherein, the first source/drain electrode portion is on a side of the gate insulation layer away from the substrate, and the interlayer insulation layer covers the first source/drain electrode portion.

4. The thin-film transistor according to claim 3, wherein, the first source/drain electrode portion is on a same layer as the gate electrode.

5. The thin-film transistor according to claim 3, wherein, the second source/drain electrode portion is of a strip-shaped structure, and an extension direction of the second source/drain electrode portion is the same as a distribution direction of the two source/drain regions; and
wherein a partial region of the first source/drain electrode portion is on a side in a width direction of the second source/drain electrode portion.

6. The thin-film transistor according to claim 5, wherein, the first source/drain electrode portion comprises a first electrode strip and a second electrode strip, an extension direction of the first electrode strip intersects with an extension direction of the second source/drain electrode portion, an end of the first electrode strip is connected with one of the two source/drain regions through a first via hole, an orthographic projection of the second electrode strip on the substrate is spaced apart from the second source/drain electrode portion, and the second electrode strip is connected with an other end of the first electrode strip.

7. The thin-film transistor according to claim 1, wherein, the first source/drain electrode portion is on a surface of the active layer away from the substrate, and the interlayer insulation layer covers the first source/drain electrode portion.

8. The thin-film transistor according to claim 1, wherein, one of the conductorization regions is within an orthographic projection region of the second source/drain electrode portion on the active layer;
wherein an other one of the conductorization regions is partially within the orthographic projection region of the second source/drain electrode portion on the active layer; or, the other one of the conductorization regions is spaced apart from the orthographic projection region of the second source/drain electrode portion on the active layer.

9. The thin-film transistor according to claim 1, wherein, the first source/drain electrode portion is on a surface of the interlayer insulation layer away from the substrate.

10. The thin-film transistor according to claim 1, wherein, the thin-film transistor comprises:
a light shielding layer, between the substrate and the active layer, wherein an orthographic projection of the active layer on the substrate is within an orthographic projection region of the light shielding layer on the substrate.

11. The thin-film transistor according to claim 10, wherein, the light shielding layer is made of a conductive material; and
wherein the light shielding layer is connected with the first source/drain electrode portion; or, the light shielding layer is connected with the gate electrode.

12. An array substrate, comprising a plurality of the thin-film transistors according to claim 1 distributed in an array.

13. The array substrate according to claim 12, wherein, the plurality of thin-film transistors distributed in an array form a plurality of transistor rows and a plurality of transistor columns, second source/drain electrode portions of a plurality of thin-film transistors in one of the transistor columns are connected in sequence, and gate electrodes of a plurality of thin-film transistors in one of the transistor rows are connected in sequence.

14. A display apparatus, comprising the array substrate according to claim 12.

15. A display apparatus, comprising the array substrate according to claim 13.

16. The thin-film transistor according to claim 2, wherein, the first source/drain electrode portion is on a side of the gate insulation layer away from the substrate, and the interlayer insulation layer covers the first source/drain electrode portion.

17. The thin-film transistor according to claim 2, wherein, the first source/drain electrode portion is on a surface of the active layer away from the substrate, and the interlayer insulation layer covers the first source/drain electrode portion.

18. The thin-film transistor according to claim 8, wherein, the first source/drain electrode portion is on a surface of the interlayer insulation layer away from the substrate.
